(19) United States
(12) Patent Application Publication
(10) Pub. No.: US 2010/0172522 A1
(43) Pub. Date: Jul. 8, 2010

(54) PROGRAMMABLE EARPHONE DEVICE WITH CUSTOMIZABLE CONTROLS AND HEARTBEAT MONITORING

(75) Inventors: David J. Mooring, Los Altos Hills, CA (US); Hans W. Klein, Danville, CA (US)

Correspondence Address: Convergent Law Group LLP, P.O. BOX 1329, MOUNTAIN VIEW, CA, 94042, US

(73) Assignee: PILLAR VENTURES, LLC, Los Altos, CA (US)

(21) Appl. No.: 12/350,011

(22) Filed: Jan. 7, 2009

(51) Int. Cl. H04R 5/02; H03G 5/00; H04R 29/00

(52) U.S. Cl. 381/311; 381/103; 381/58

(57) ABSTRACT

Methods and systems for providing a programmable earphone device with customizable controls and heartbeat monitoring are described. The earphone device may include a wireless connection to a media player, a left and a right earphone, and at least one input mechanism, wherein the input mechanism is located on at least one of the left and right earphones and is customizable. The earphone device may also include an data port configured to bypass the wireless connection and receive sound data from the media player when a wired connection is detected between the media player and the earphone device. A stored customizable sound equalizer may also be included that provides different equalizer settings for each of the left and right earphones. The earphone device also includes a heartbeat monitor that detects a user's heartbeat using the left and right earphone, wherein the heartbeat monitor is customizable by the user.

### BACKGROUND OF THE INVENTION

Small, portable media player devices, such as digital audio players (e.g., iPods, marked by Apple Incorporated of Cupertino, Calif., and other such products) have become very popular. These media players generally require the use of external listening devices, such as loudspeakers, headphones, or small form-factor “ear-phones” or “ear-buds” to output sound. Ear-buds are popular among users, owing in part to their small size and relative inexpensiveness of production. In particular, due to their light weight and small size, ear-buds are typically the preferred listening device for use during physical exercise.

Headphones and ear-buds are typically connected to the audio player via a cable. While this is an interconnect method offering high sound quality at low-cost, the wire itself can sometimes be inconvenient or even hindering in a user's activity. For example, during physical exercise, people often listen to their personal music, carrying the player in a pocket or small pouch. With the media player connected to the ear-buds via wires, the wires can get entangled with work-out equipment, bounce around due to the work-out motion, or pull on the ear-buds, thus creating a nuisance to the user, if not a safety issue.

Wireless products offer an attractive alternative by replacing the interconnecting wire with a radio frequency (“RF”) link, such as BlueTooth™. In addition, wireless headphones (or ear-buds) are often designed to “pair” with other electronic devices as well, such as cell-phones, which often can act as media players in addition to providing telephone capabilities. Due to the electronics required inside the wireless listening device, which at a minimum include an RF receiver and sound amplifier, wireless listening devices conventionally have at least one switch to power an electronic circuit on and off. Additional buttons may be provided to control additional functionality, such as initiating or ending a telephone call and for volume control.

The switches or buttons of such wireless listening devices, however, may be difficult to operate and may only provide limited functionality. For example, to change the sound of music presented to the user's ear, it is conventionally required to use the media player, which usually must be removed from its container, to edit the sound equalizer function (or equivalent) and/or change to the playback settings. The media player must usually then be put back into its original place, such as inside a pocket or pouch.

It is also possible with conventional media players to modify the listening experience by amplifying or attenuating certain frequency ranges. This can typically be accomplished by selecting from preset choices in the media player, or by using customizable filters, available from a function sometimes referred to as a sound equalizer (“EQ”). Such features conventionally allow the user to select from a number of frequency bands and make frequency amplification or attenuation choices to their liking. However, in conventional media players, the sound EQ settings are applied equally to both left and right music channels. This may not be optimal for users loss. whose hearing ability substantially differs between their left and right ears. Such differences may be caused, for example, by imbalance hearing loss in both ears, or a loss of hearing in only one ear.

Also, a variety of consumer products exist in the market for heart rate monitoring (“HRM”). As opposed to medical devices that are designed to record or analyze a heart beat signal (commonly known as the “QRS complex”) with great detail and accuracy, these consumer products are targeted at simply monitoring heart rate while users perform physical exercise. Consumer devices conventionally only require two or three electrodes, as opposed to five or more in medical or analytical devices. In consumer devices, it is typical for said electrodes to be embedded in a flexible chest strap, making contact to the skin across the wearer's chest, and thereby picking up electrical signals associated with heartbeat activity. These electrodes, just like with their medical device counterparts, are placed in the general chest area because this provides for an electrical signal with highest amplitude. While placing electrodes on the user's chest may simplify the electronic signal processing circuit, it is possible to detect heartbeat signals across other locations on the body, such as left and right limbs.

Wherever the electrodes are placed, for conventional heart monitors the electrodes typically must provide a differential signal, which is typically achieved by placing electrodes somewhat symmetrically around the heart. For example, placing one electrode on each shoulder will provide a similar signal as picked up by two electrodes across the left and right side of the chest. Locations on the left and right side of the neck, or even the head, can be used as well, although the greater distance from the heart gradually weakens the signal amplitude.

Regardless of the general location of the electrodes on the body, as the distance between the electrodes decreases, so does the heart beat signal. Also, as the distance from the chest area is increased and the electrodes are placed closer together, the signal amplitude further decreases and it becomes increasingly difficult to obtain a quality signal. In addition, electrodes conventionally must maintain good electrical contact to the skin at all times in order to provide a quality signal to the heartbeat-detecting circuit. However, chest straps are undesirable because the straps may add to the cost of the heartbeat-detecting devices, can be cumbersome to set up, and may cause discomfort or an appearance that is unfashionable.

In order to increase the appeal and utility of electronic products, oftentimes features are added. However, a rich set of features is increasingly difficult for a user to manage and use, as often only a limited number of buttons or other controls are available. For example, some advanced cell-phones allow certain buttons to be programmed to execute user-specified applications, such as an address book. Such customization of controls results in greater user satisfaction, as the functions of interest are more easily and more quickly invoked. However, thus far no rich functionality is available in head-phones, leave alone small ear-buds, because of the very limited capability of conventional controls (e.g., buttons). If several new features would be made available for ear-buds, as exemplified herein before, quite quickly the user interface would become increasingly cumbersome and thus defeat the original intent of greater user satisfaction.

### BRIEF SUMMARY OF THE INVENTION

Methods and systems for providing a programmable earphone device with customizable controls, and heartbeat monitoring are described. In one embodiment, the earphone device may include a wireless transceiver that has a wireless connection to a media player; a left and right earphone for a user's left and right ear; a stored customizable sound equalizer comprising a left ear equalizer setting and a right ear equalizer setting, wherein the left ear equalizer setting is different from the right ear equalizer setting; and a heartbeat monitor configured to detect a user's heartbeat using the left and right earphone, wherein the heartbeat monitor is customizable by the user.

In another embodiment, the programmable earphone device may include a left and right earphone for a user's left and right ear; a wireless transceiver that has a wireless connection to a media player; an data port, wherein the data port is configured to bypass the wireless connection and output sound data from the media player when a wired connection is detected between the media player and the earphone device through the data port; and a heartbeat monitor configured to detect a user's heartbeat using the left and right earphone, wherein the heartbeat monitor is customizable by the user.

In another embodiment, the earphone device may include a wireless transceiver that has a wireless connection to a media player, a left and a right earphone for a user's left and right ear, and at least one input mechanism, wherein the input mechanism is located on at least one of the left and right earphones and a function of the input mechanism is customizable by the user. The earphone device may also include an data port, wherein the data port is configured to bypass the wireless connection and receive sound data from the media player when a wired connection is created between the media player and the earphone device through the data port. A stored customizable sound equalizer may also be included, wherein the stored customizable sound equalizer provides different equalizer settings for each of the left and right earphones. The earphone device also includes a heartbeat monitor configured to detect a user's heartbeat using the left and right earphone, wherein the heartbeat monitor is customizable by the user.

In yet a further embodiment, a method for configuring a programmable earphone device is provided. The method includes testing a sensitivity of a user's left and right ears separately using the programmable earphone device, wherein the programmable earphone device comprises a left and right earphone for the user's left and right ears, to determine a difference in sensitivity between the user's left and right ears; calculating a left ear equalizer setting and a right ear equalizer setting, wherein the left ear equalizer setting is different from the right ear equalizer setting, using the difference in sensitivity between the user's left and right ears; and saving the left ear equalizer setting and the right ear equalizer setting to a non-volatile memory of the earphone device.

In yet another embodiment, a system is provided that includes a programmable earphone device comprising a heartbeat monitoring application and a user interface; and a custom user interface web service, wherein the programmable earphone device is in communication with the custom user interface web service, and the custom user interface web service is configured to allow a user to configure and reconfigure at least one of the heartbeat monitoring application and the user interface.

### BRIEF DESCRIPTION OF SEVERAL VIEWS OF THE DRAWINGS

The drawings illustrate the design and utility of embodiments of the invention, in which similar elements are referred to by common reference numerals. In order to better appreciate the embodiments, reference should be made to the accompanying drawings that illustrate these embodiments. However, the drawings depict only some embodiments of the invention, and should not be taken as limiting its scope. With this caveat, embodiments of the invention will be described and explained with additional specificity and detail through the use of the accompanying drawings in which:

FIG. 1 is a block diagram illustrating an exemplary embodiment of a system including a programmable earphone device with customizable controls and heartbeat monitoring.

FIG. 2 is a block diagram illustrating an exemplary embodiment of an electronic unit of a programmable earphone device with customizable controls and heartbeat monitoring.

FIG. 3 is a diagram illustrating an exemplary embodiment of a programmable earphone device with customizable controls and heartbeat monitoring.

FIG. 4 illustrates an exemplary embodiment of a process for providing a programmable earphone device with customizable controls and heartbeat monitoring.

FIG. 5 illustrates an exemplary embodiment of a process for providing a programmable earphone device with customizable sound equalizers for a left and right sound channel.

FIG. 6 illustrates an exemplary embodiment of a process for providing a programmable wireless earphone device with a wired bypass mode.

FIG. 7 is a diagram illustrating communication between an exemplary programmable earphone device with customizable controls and heartbeat monitoring and an exemplary custom user interface web service.

### DETAILED DESCRIPTION OF THE INVENTION

The present invention relates to providing a programmable earphone device with customizable controls and heartbeat monitoring. The following description is presented to enable one of ordinary skill in the art to make and use the invention and is provided in the context of a patent application and its requirements. Various modifications to the embodiments and the generic principles and features described herein can be made. Thus, the present invention is not intended to be limited to the embodiments shown, but is to be accorded the widest scope consistent with the principles and features described herein.

In the following description, for purposes of explanation, numerous details are set forth in order to provide a thorough understanding of various embodiments. It is important to note that the invention can be practiced without all of these details. Reference in this specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments.

The exemplary embodiment provides methods and systems for an earphone device that is customizable and may provide a wide variety of functionality. The earphone device includes a wired or wireless connection to a media player, and may also include a stored customizable sound filter, also known as a sound equalizer (“EQ”). Having a stored EQ onboard the earphones allows a user's personalized EQ settings to be used with any media player the earphone device is paired with, without requiring the user to adjust EQ settings on the media player. The user may configure an EQ setting for each ear (i.e., the left and right sound channel) to account for differences in the user's hearing in each ear.

The earphone device may also have a wired “bypass” mode wherein a wireless connection is deactivated, and the earphone device receives sound data through a wired connection, such as a USB cable or a 2.5 mm cable. Additionally the earphone device may include a heartbeat signal monitoring function wherein electrodes may be used to sense a user's heartbeat signal, thereby eliminating the need for chest straps or other extraneous devices conventionally used for monitoring heartbeat. The parameters (e.g., under what conditions heartbeat monitoring is performed, what data is stored on the media player device, etc.) for heartbeat monitoring may be configured by the user.

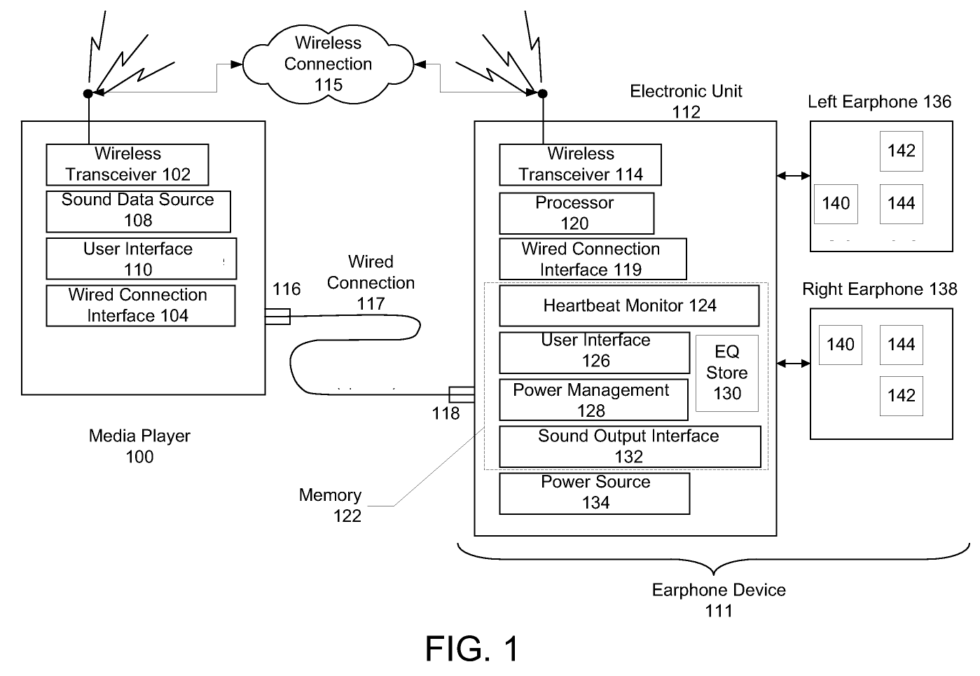

FIG. 1 is a block diagram illustrating an exemplary embodiment of a system including a programmable earphone device 111 with customizable controls and heartbeat monitoring. The earphone device 111 may include electronic unit 112, left earphone 136, and right earphone 138, and may take a variety of form factors, including earphones, ear-buds, and the like. The earphone device 111 may be in communication with media player 100, through a wireless connection 115 or a wired connection 117, over which sound data may be transmitted to the earphone device 111.

The media player 100 may be any electronic device capable of producing audio sound data (e.g., a portable music player, a portable video player, a smart mobile telephone or other communications device, a handheld computer, a laptop, etc.). The media player 100 may include a wireless transceiver 102, which may either be internal to the media player 100, or an external unit that plugs into a sound data port of the media player 100 (e.g., the headphone socket). The media player 100 may also include a wired connection interface 104, which can be used to send sound data through sound data plug 106 of the media player 100 to the sound data plug 118 of the earphone device 111 through wired connection 117. The sound data, transmitted through the wireless transceiver 102 and/or the wired connection interface 104 may be produced by a sound data source 108, which may be any application on the media player 100 that produces sound data (e.g., video and/or audio player applications, an internet browser application, a telephone application, etc.). The media player 100 may also include its own user interface (UI) 110, which may enable the user to interact with the media player and perform various functions, including functions relating to media playback, audio settings, and the like.

In the exemplary embodiment, the electronic unit 112 of the earphone device 111 may include a wireless transceiver 114, an data port 118, a processor 120, a wired connection 116, a memory 122 and a power source 134. Sound data may be received from the media player 100 wirelessly via the wireless transceiver 114 and the wireless connection 115, which may use any suitable wireless technology for the transmission of sound data (e.g., Wi-Fi®, Bluetooth®, ultra-wideband, etc.). Sound data may also be received through the wired connection interface 119, which can receive sound data through data port 118 of the electronic unit 112 from the media player 100 through wired connection 117. Wired connection 117 may include any suitable wired technology for the transmission of sound data (e.g., a USB connection, a 3.5 mm or 2.5 mm TRS connection, a FireWire connection, etc.). Likewise, data port 118 can include one or more of a USB port, a FireWire port, and/or a 3.5 mm and a 2.5 mm TRS connection. As described below, the data port 118 may be configured to automatically bypass the wireless connection 115 and receive sound data from the media player 100 when a wired connection 117 is detected between the media player 100 and the earphone device 111 through the data port 118.

Wireless transceiver 114 and wired connection interface 119 may be coupled to processor 120, which may provide various functionality for the earphone device 111. The processor 120 may be coupled to a memory 122, which may store applications and settings for a heartbeat monitor 124, a user interface 126, power management 128 and sound output interface 132. The heartbeat monitor 124 may include a detection application that can track the user's heartbeat using heartbeat monitor 142, and may also contain data regarding the user's target heartbeat range. The heartbeat monitor 124 may also be configured to announce heartbeat information to the user through speakers 140, and to provide a sound indicator that the user has entered and/or exited, the target heartbeat range. Heartbeat monitor 142 may include any electronic or electromechanical devices used to measure the user's heartbeat, such as electrodes, or ECM microphones, for example.

The user interface 126 may enable the user to interact with the earphone device 111 and control the functionality thereof. For example, the user interface 126 may be used to enable or disable the use of a user EQ profile (described below), to change the playback properties of received sound data (e.g., change the volume, or deactivate sound in one of the left earphone 136 and the right earphone 138), and/or to control the functionality of the heartbeat detection application 124 (e.g., turn on/off the reporting of the user's heartbeat, request reporting of a user's workout summary, etc.).

The user may interact with the user interface 126 using at least one input mechanism 144, which may include one or more buttons, dials, and/or touch sensors. The input mechanism 144 may be located on at least one of the left and right earphones in one embodiment, and a function of the input mechanism is customizable by the user, for example, to recognize user-defined commands stored within the user interface 126.

For example, the user may use one or more touch sensors to create user-defined commands to monitor the user's heartbeat, or to deactivate the music playback in a selected one of the left and right earphones. In an exemplary embodiment, a microphone (not shown) may be located on at least one of the left earphone 136 and the right earphone 138, wherein the microphone is configured to turn on and provide ambient sound to the user through the selected earphone. This may be desirable, for example, when a bicycle rider is wearing the electronic device 111. When crossing an intersection, the bicycle rider may wish to deactivate the selected earphone to better hear ambient sounds, such as oncoming cars.

As stated above, one or more touch sensors can be located on at least one of the left and right earphones. In one embodiment, a single touch sensor can be located near the center of an ear-bud housing, which can advantageously allow a user to easily locate and touch the sensor. There are several ways the touch sensor can receive inputs: one example is to evaluate the duration of the touch (such as in “touch-and-hold”), another example is to detect multiple taps (e.g., “tap-tap-tap”). Yet another example is sliding a finger across the sensor in a sideways or vertical-direction. Combinations of these modes of touch can be utilized to implement very intuitive control mechanisms. An example embodiment can be to use each short tap to increase playback volume, whereas holding the touch would decrease the volume at a certain rate. Another example of using touch commands to interact with the user interface 126 can be having a first touch temporarily mute the music playback function, and a second tap reactivates the playback. Yet another example is to use a single tap to trigger the announcement of a user's heart rate, which may be synthesized and spoken by a computing unit. Using a touch-based system of user inputs may be advantageous because the touch inputs may reduce or eliminate the need for small buttons, volume sliders, and/or wheels. The touch sensors can be configured to act intuitively and ergonomically, especially while the user performs physical exercise. In one embodiment, the touch sensors may be based on a resistance measurement method, where it is necessary to actually touch the surface. In another embodiment, the touch sensors may be based on inductive or capacitive principles that don't require an actual touch, but merely a very close proximity to the sensing surface.

Additionally, touch controls may be implemented in addition to conventional push-button controls. Such a dual-mode unit may include at least one conventional button, such as an on/off type push button, and at least one touch sensor element on the button's surface. Thus, a gentle touch, insufficient in force to actuate the conventional push button, could be detected by the touch sensor's electronic circuit. However, if the user were to depress the button more forcefully, the conventional push button function would be actuated and correspondingly evaluated by the user interface 126. An exemplary use of such dual-mode unit would utilize the volume-control of the touch sensor on the button as described herein previously, and have actuating the push-button action invoke another function, such as powering the earphone device 111 on/off. Such a dual-function input mechanism 144 could reduce the number of mechanical buttons, sliders, and wheels while increasing the intuitive use by means of a combined touch-sensor and a push-button.

The power management application 128 may communicate with the processor 120 and coordinate power management for the earphone device 111 while the earphone device 111 draws power from the power source 134. In one embodiment, the power source 134 may be a rechargeable, lithium ion battery, or the like. The power management application 128 may also control power-saving functionality of the earphone device 111, such as a timer function. The timer function may, for example, turn off the earphone device 111 if the wireless connection 115 is lost for a predetermined amount of time, or if no sound data is received by either the wireless transceiver 114 or the wired connection interface 119 for a predetermined amount of time.

In an exemplary embodiment, the user may customize the predetermined amount of time used by the timer function. For example, if a user regularly halts the music player in order to have a brief conversation and then resumes the music playback, the user can advantageously set the predetermined amount of time to be longer than a default period, such as 10 or 20 minutes, thereby preventing accidental powering down of the earphone device 111. However, because concerns about conserving power consumption in small wireless ear-phone products, it is generally desirable to maximize the usable operating life off of a given battery charge. Therefore, the user who wishes to maximize operating life of the power source 134 may prefer to set the predetermined amount of time to be shorter, such as 1 or 3 minutes. In embodiments with the timer function, a power-off function may be omitted for the earphone device 111 altogether, thereby simplifying the number of buttons required and/or simplifying the user interface 126.

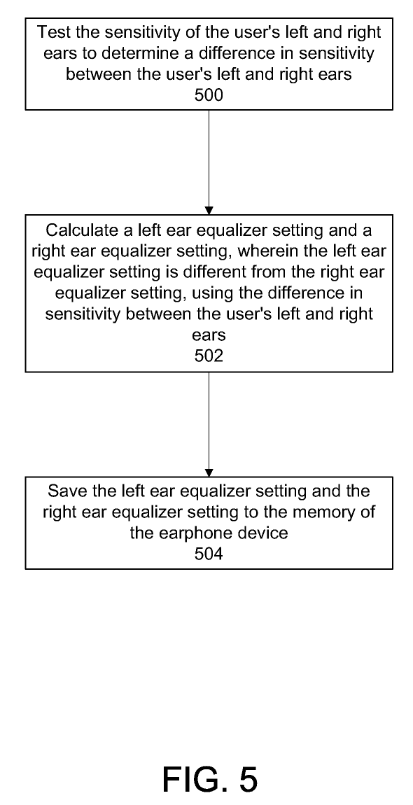

The memory 122 may also include EQ profile store 130, which may contain one or more EQ profiles. The EQ profiles may be selectable by the user, and may include EQ settings for different types of sound data (e.g., different genres of music, or for video playback). In the exemplary embodiment, an EQ profile may provide different equalizer settings for each of the left and right earphones to account for sensitivity differences in a user's left and right ears. This embodiment is described in further detail below, in the discussion of FIG. 5.

After sound data is received from, for example, the wireless transceiver 114 and/or the wired connection interface 119, it may be processed using sound EQ settings from one or more of the EQ profiles, then transferred to the sound output interface 132, which together with the processor 120 may convert the received data from the wireless connection 115 or the wired connection 117 into audible sound, which may include, for example, decompression and decoding of the digital signal. Applying the sound EQ settings may be performed while the music stream is still in digital format, by the processor 120, in an exemplary embodiment. In another embodiment, the sound EQ settings may be applied by the sound output interface 132 after the sound has been converted to analog waveforms using analog circuitry. Either way, the sound EQ processing involves the implementation of filters, arranged in a multitude of known ways. After the sound EQ settings are applied, the processed sound data may be output through speakers 140.

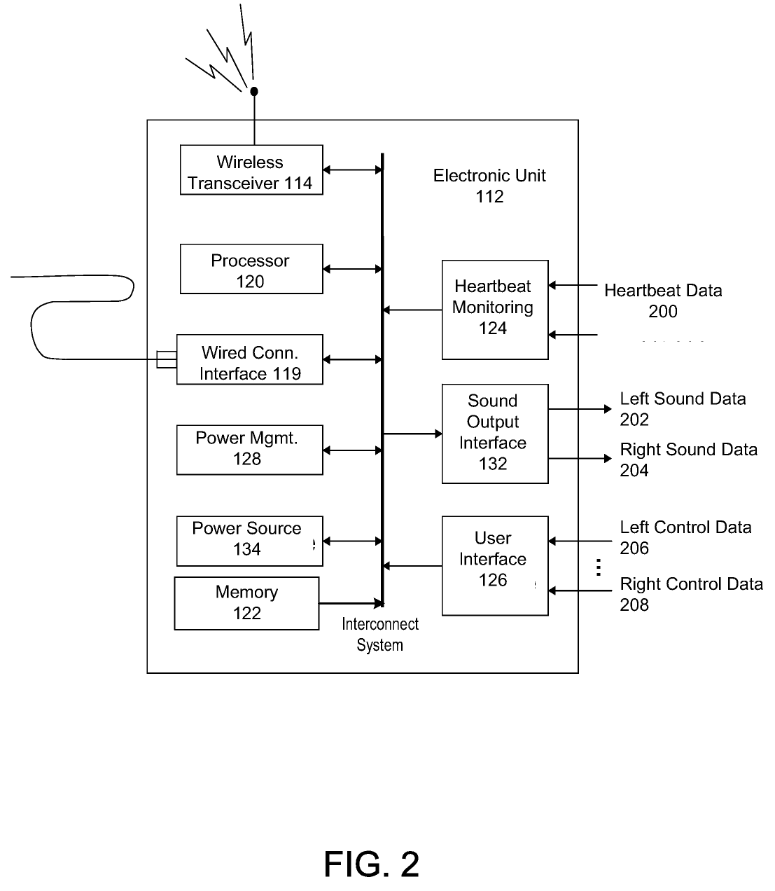

FIG. 2 is a block diagram illustrating another exemplary embodiment of an electronic unit 112 of a programmable earphone device 111 with customizable controls and heartbeat monitoring. The electronic unit 112, as shown, may be coupled to each of the left earphone 136 and right earphone 138. Wireless transceiver 114, wired connection interface 119, processor 120, power management application 128, power source 134, heartbeat monitoring application 124, sound output interface 132 and user interface 126 are all shown in FIG. 2, and function as described above. As shown in FIG. 2, heartbeat data 200 may be received from each of the right and left heartbeat monitors 142. Similarly, left and right sound data 202 and 204 may be output to left and right speakers 140, respectively, from the sound output interface 132, and left and right control data 206 and 208 may be received from input mechanisms 144.

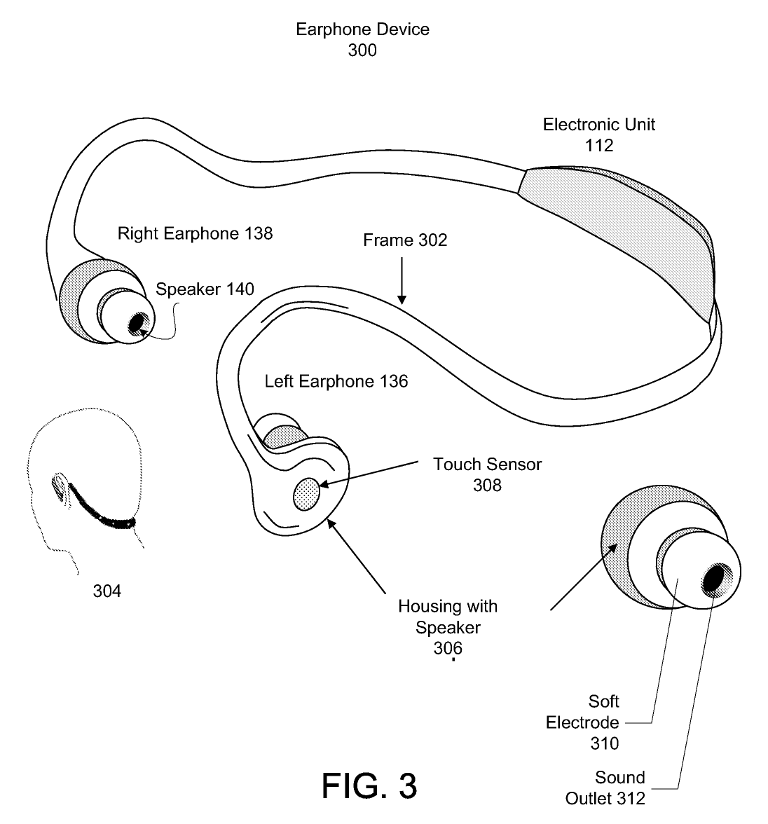

A wide variety of physical configurations may be used for the earphone device 111. FIG. 3 is a diagram illustrating an exemplary embodiment of a programmable earphone device 300 with customizable controls and heartbeat monitoring. The earphone device 300 includes the electronic unit 112 connected to the left earphone 136 and the right earphone 138 by frame 302, which can be a semi-flexible body substantially contoured to fit the shape of the user's head. The earphone device 300 may be worn in the manner shown in diagram 304, with the electronic unit 112 located behind the user's head, which may be advantageous because of the absence of any loose connecting wires, which can move around and annoy the user while the earphone device is used during exercise, for example.

Each of the left earphone 136 and the right earphone 138 may include a speaker housing 306 that includes the speaker 140 (see FIGS. 1 and 3). Speaker 140, upon receiving sound data, can output the corresponding sound through sound outlet 312. On the outside of the speaker housing 306 of the exemplary embodiment is a touch sensor 308, which can perform the function of the input mechanism 144 described above. The electrode 310, similarly, may perform the function of the heartbeat monitor 142 described above. The electrode 310 may be located on the inside of the speaker housing 306, and may be composed of a soft gel to advantageously provide a comfortable, secure contact to the user's ear for heartbeat monitoring.

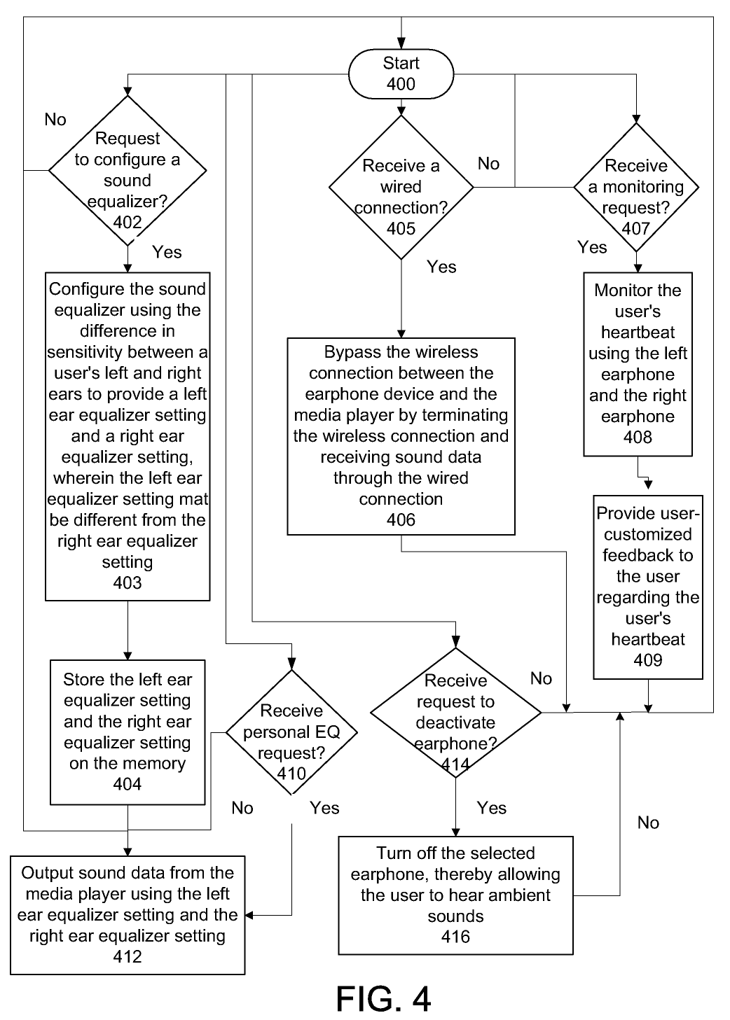

FIG. 4 illustrates an exemplary embodiment of a process for providing a programmable earphone device 111 with customizable controls and heartbeat monitoring. After the start of the process (block 400), the earphone device 111 can be responsive to a plurality of user requests. For example, a user may request to configure a sound equalizer (block 402). The sound equalizer may be configured using the difference in sensitivity between a user's left and right ears to provide a left ear equalizer setting and a right ear equalizer setting, wherein the left ear equalizer setting may be different from the right ear equalizer setting (block 403). The left ear equalizer setting and right ear equalizer setting may be set in a variety of ways, and may be set either when the earphone device 111 is connected to a docking device (e.g., a computer, a handheld computer, a smart phone, etc.), or by the earphone device 111 alone (e.g., in response to a command received by the user interface 126, entering a “configuration mode”). An exemplary embodiment of configuring a sound equalizer to provide a left ear equalizer setting and a right ear equalizer setting as described herein is shown below, in FIG. 5. The left ear equalizer setting and the right ear equalizer setting are then stored in the memory 122 within the earphone device 111 (block 404).

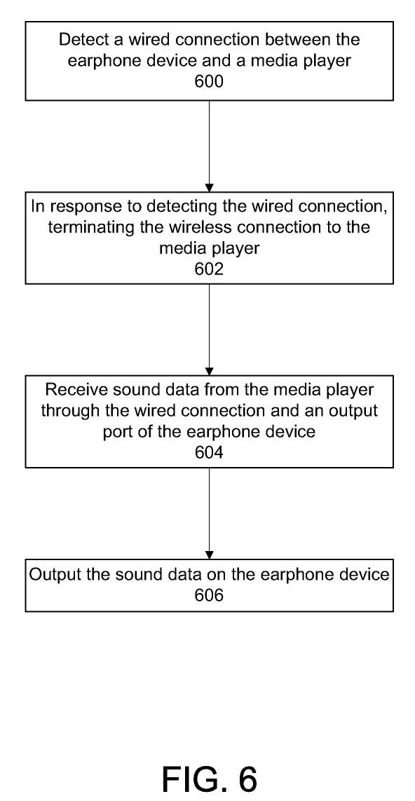

The earphone device may also receive a wired connection 117 (block 405). In response to receiving the wired connection 117, the wireless connection 115 between the earphone device 111 and the media player 100 may be bypassed by terminating the wireless connection 115 and receiving sound data through the wired connection 117 (block 406). An exemplary embodiment of bypassing the wireless connection 115 in favor of the wired connection 117 as described herein is shown below, in FIG. 6.

A user may also make a monitoring request for the earphone device 111 to monitor the user's heartbeat (block 407). In response to a monitoring request, the user's heartbeat may be monitored using the left earphone 136 and the right earphone 138, wherein the heartbeat monitor 124 is customizable by the user to provide heartbeat data (block 408). The heartbeat monitoring is performed by the heartbeat monitoring application 124 and the heartbeat monitors 142, and a variety of different technologies may be used. While a preferred embodiment uses electrodes as the heartbeat monitors 142 as part of an electrical heart monitoring system, other methods, such as acoustical, optical, and/or mechanical systems may be used. In conjunction with the heartbeat monitoring, user-customized feedback may be provided to the user regarding the user's heartbeat (block 409). As stated above, the feedback may be selected by the user, and the feedback can be configured to be provided automatically, or in response to a user-defined command. The feedback can include any heartbeat related data that is measured, including at least one of a user's current heart rate, reaching a target heart range for a user, and a time period spent in the target heart range or a plurality of target heart ranges, for example.

A user may also make a personal EQ request to use the stored EQ settings (block 410). In response to the personal EQ request, sound data from the media player 100 may be output on the speakers 140 using the left ear equalizer setting and the right ear equalizer setting (block 412).

As stated above, the user may have access to a variety of different EQ settings stored within EQ store 130. In an exemplary embodiment, the user may request that sound be deactivated in one of the earphones (block 414). This can be done, for example by a two-fingered sliding motion on the edge of the touch sensor 308 of the selected earphone. In response to the deactivation request, the selected earphone can be turned off, thereby allowing the user to hear ambient sounds. (block 416) In an exemplary embodiment, a microphone on the selected earphone or elsewhere on the earphone device 111 can be turned on when the selected earphone's music playback is turned off, thereby enhancing the user's ability to hear ambient sounds. The selected playback can remain deactivated until a user request to reactivate the selected earphone playback is received, which can be the same command used to deactivate the selected earphone, for example. By deactivating a selected earphone, the user can listen to a conversation with another person (such as deactivating one earphone to listen to a stewardess on an airplane), or listen for ambient sounds (such as an approaching car, or siren, for example) without physically removing the earphone device 111 from the user's ear.

Conventional media players provide means to modify the sound of the playback signal, such as amplifying or attenuating certain frequency bands. This function is generally referred to as sound equalization. Furthermore, the sound EQ settings for both left & right audio channels are conventionally identical. However, an increasing number of people suffer from hearing loss which comes in many different forms. One of them is simply the loss in sensitivity of higher frequencies, which often progresses with age. Another example is the loss of a narrow frequency spectrum. Such loss of hearing sensitivity can affect both ears, but not always to the same degree. Also, accidents, illness or other events can impact a person's hearing ability and it can affect one ear quite differently from the other.

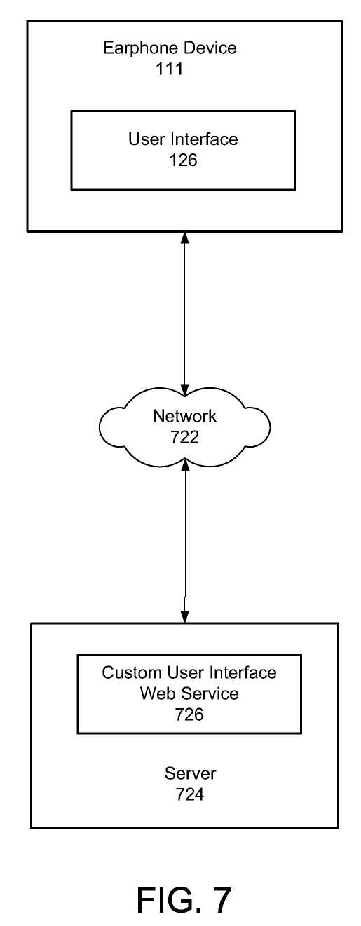

FIG. 5 illustrates an exemplary embodiment of a process for providing a programmable earphone device 111 with customizable sound equalizers for a left and right sound channel. The sound EQ configuration process may be implemented by, for example, an application on a personal computer and/or a web service such as the one shown below in FIG. 7. The sound EQ configuration process may allow the user to customize the EQ settings and download and store the EQ settings in the earphone device 111. The EQ settings can therefore be preserved on the earphone device 111, even when the power source 134 is replaced or discharged.

The sensitivity of the user's left and right ears may be tested separately using the left earphone 136 and right earphone 138 of the earphone device 111 to determine a difference in sensitivity between the user's left and right ears (block 500). This can be done, for example, when the user connects the earphone device 111 to a computer's sound output device, via audio jacks, USB ports, or wirelessly, for example. The user can then enter a testing mode, wherein a sequence of audio tests is performed with the ear-phones 136 and 138 inserted in the user's ears. In one possible embodiment of an audio test, a series of tones is played, at different frequencies and amplitudes, whilst the user provides feedback to the computer via keyboard or mouse or other input device. For example, the sequence could start with a tone of certain frequency being played in one ear, beginning from low (inaudible) levels to increasingly louder levels, for a predetermined period of time with a predetermined amount of amplitude increase. The user may then indicate when a tone is detected by the user by pressing a button, which would indicate that the concurrently played tone is at the sensitivity threshold of the listener.

Repeating the same tone sequence for the other ear, and again getting the listener to provide feedback at the threshold of hearing the tone, can permit the difference in sensitivity between the left and right ear to be calculated. Repeating this test at additional frequencies, and possibly rerunning the entire sequence multiple times or in different ways for better accuracy, the complete hearing spectrum for each ear can be determined over the entire audio frequency range supported by the earphone device 111. Thus, at the end of the audio test sequence, sufficient hearing data is generated to calculate the final sound-EQ settings for each left and right channel.

A left ear equalizer setting and a right ear equalizer setting may be calculated, wherein the left ear equalizer setting is different from the right ear equalizer setting, using the difference in sensitivity between the user's left and right ears (block 502). In one embodiment, once the sensitivity for each ear is calculated, referred to as a sensitivity curve, EQ correction settings may be provided to compensate for the difference in each ear relative to a “normal” hearing sensitivity. The EQ correction setting may be determined by dividing the respective sensitivity curves by that of a “normal” curve, resulting in certain amplification values at their respective frequency points, and interpolation in between, so as to correct for hearing loss across the entire audio frequency range. The left ear equalizer setting and the right ear equalizer setting may then be saved to the memory 122 of the earphone device 111 (block 504). In an exemplary embodiment, the left ear equalizer setting and the right ear equalizer setting may be saved in a personal EQ profile in the EQ store 130.

Music being played back through these uniquely configured left and right sound-EQs may then produce a balanced sound experience, as the listener's personal hearing sensitivity has been substantially compensated for across the entire audio spectrum supported by the earphone device 111. Therefore, the user may benefit from sound-EQ processing individually optimized to the user's left and right-ear hearing ability, without requiring a costly and time consuming testing by an audiologist. The left ear equalizer setting and the right ear equalizer setting on the earphone device may be usable on a plurality of different media players, and are not restricted to being paired with any single media player.

Although wireless operation of the earphone device 111 may be advantageous to avoid the use of dangling wires, particularly, when the user is exercising, the user may wish to use the earphone device with a wired connection to the media player 100. FIG. 6 illustrates an exemplary embodiment of a process for providing a programmable wireless earphone device 111 with a wired bypass mode. A wired connection 115 is detected between the earphone device 111 and a media player 100 (block 600). The wired connection 115 can include any supported wired connection, including any of a USB, FireWire, and/or TRS connection of any size. In response to detecting the wired connection 115, the wireless connection 117 to the media player 100 is terminated (602) in an exemplary embodiment, which may be advantageous to reduce power consumption. Sound data is received from the media player 100 through the wired connection 117 and data port 118 of the earphone device (block 604) as described above. The sound data is then output on the earphone device 111 (block 606) through the speakers 140. In an exemplary embodiment, power can be supplied to recharge the power source 134 through the wired connection 117 (e.g., if the wired connection 117 is a USB or FireWire connection).

In an exemplary embodiment, sound data may be output using an EQ profile stored on the earphone device 111, wherein the EQ profile comprises different sound equalizer settings for each of a user's left and right ears, when the wired connection 117 is detected. Also, sound data may be output without using the EQ profile when the wired connection 117 is detected and the EQ profile is deactivated.

The aforementioned bypass functionality can allow the earphone device 111 and personal sound EQ settings to be used with products not supporting a compatible wireless connection (e.g., an airplane speaker socket, and/or the media player of another person). Additionally, the bypass functionality can be advantageous because it can be used to bypass use of an available wireless connection if so desired by the user (e.g., to save battery life).

The functionality of the earphone device 111 can be modified by the user and stored on the memory 122 of the earphone device 111. The modification can be performed on an application running on a computer, a portable electronic device, and/or a web service. FIG. 7 is a diagram illustrating communication between an exemplary programmable earphone device 111 with customizable controls and heartbeat monitoring and an exemplary custom user interface web service. As stated above, the user can customize, or personalize, the set of available functions and how to control them using the user interface 126. The earphone device 111 can be in communication with a computing device, such as a laptop, or a custom user interface web service 726, which may be provided by a server 724, through a network 722. The custom user interface web service 726 may contain modified settings for the user interface 126 and allow the user to customize the user interface 126 and download the changes to the earphone device 111.

For example, a left-handed user may prefer using the touch sensor on the left ear-bud 136 to control the volume, whereas a right-handed user might choose the opposite. Another example would be assigning a heart rate announcement to one sensor, in response to a single “tap”, but not allow any other function. In the latter case, whenever the user would place a finger on the sensor, a short “tap”, or a longer “hold”, in either case the system would execute just the single function assigned, in this example the announcement of the current heart rate. These changes may be implemented by selection from a menu on the web service 726 or equivalent program running on a user's computing device.

The custom user interface web service 726 in an exemplary embodiment may also permit the user to download a personal alert/message tone (e.g., for use in heartbeat monitoring feedback), upload work-out results and track the work-out results online over time, and order different “skins” or other cosmetic accessories for the earphone device 111.

A method and system for providing a programmable earphone device with customizable heartbeat monitoring has been disclosed. The present invention is mainly described in terms of particular systems provided in particular implementations. However, this method and system may operate effectively in other implementations. For example, the systems, devices, and networks usable with the present invention can take a number of different forms. The present invention will also be described in the context of particular methods having certain steps. However, the method and system operate effectively for other methods having different and/or additional steps or steps in a different order not inconsistent with the present invention.

The present invention has been described in accordance with the embodiments shown, and there could be variations to the embodiments, and any variations would be within the scope of the present invention. For example, the present invention can be implemented using hardware, software, a computer readable medium containing program instructions, or a combination thereof. Software written according to the present invention is to be either stored in some form of computer-readable medium such as memory or CD-ROM, and is to be executed by a processor. Accordingly, many modifications may be made without departing from the scope of the appended claims.

We claim:

1. A programmable earphone device, comprising:
a wireless transceiver that has a wireless connection to a media player;
a left and a right earphone for a user's left and right ear;
at least one input mechanism, wherein the input mechanism is located on at least one of the left and right earphones and a function of the input mechanism is customizable by the user;
a data port, wherein the data port is configured to bypass the wireless connection and receive sound data from the media player when a wired connection is created between the media player and the programmable earphone device through the data port;
a stored customizable sound equalizer, wherein the stored customizable sound equalizer provides different equalizer settings for each of the left and right earphones; and
a heartbeat monitor configured to detect a user's heartbeat using the left and right earphone, wherein the heartbeat monitor is customizable by the user.

2. The programmable earphone device of claim 1 wherein the input mechanism is configured by the user to recognize user-defined commands and wherein the input mechanism is configured to receive a monitoring request to monitor the user's heartbeat.

3. The programmable earphone device of claim 2 wherein the input mechanism is configured to receive a request to deactivate sound in one of the left and right earphones.

4. The programmable earphone device of claim 3 further comprising a microphone located on at least one of the left and right earphones, wherein the microphone is configured to turn on and provide ambient sound to the user through the deactivated earphone.

5. The programmable earphone device of claim 2 wherein the input mechanism comprises at least one touch sensor.

6. The programmable earphone device of claim 2 wherein the user-defined commands are contained in a user interface stored in a non-volatile memory within the programmable earphone device.

7. The programmable earphone device of claim 1 further comprising a timer function that turns off the programmable earphone device if the wireless connection is lost for a predetermined amount of time.

8. A method for providing a programmable earphone device, comprising:
configuring a sound equalizer using a difference in sensitivity between a user's left and right ears to provide a left ear equalizer setting and a right ear equalizer setting, wherein the left ear equalizer setting is different from the right ear equalizer setting;
storing the left ear equalizer setting and the right ear equalizer setting in a non-volatile memory within the programmable earphone device;
in response to receiving a wired connection, bypassing a wireless connection between the programmable earphone device and a media player by terminating the wireless connection and receiving sound data through the wired connection; and
in response to receiving a heartbeat monitoring request, monitoring a user's heartbeat using a left earphone and a right earphone, wherein heartbeat monitoring is customizable by the user to provide heartbeat data.

9. The method of claim 8 further comprising receiving the heartbeat monitoring request via an input mechanism, wherein the input mechanism is located on at least one of left and right earphones, wherein at least one function of the input mechanism is customizable by the user to recognize user-defined commands, and wherein the input mechanism is configured to receive the monitoring request to monitor the user's heartbeat.

10. The method of claim 9 wherein the input mechanism is configured to receive a request to deactivate sound in one of the left and right earphones.

11. The method of claim 10 further comprising a microphone located on at least one of the left and right earphones, wherein the microphone is configured to turn on and provide ambient sound to the user through the deactivated earphone.

12. The method of claim 9 wherein the input mechanism comprises at least one touch sensor.

13. The method of claim 9 further comprising storing the user-defined commands in the non-volatile memory within the programmable earphone device.

14. The method of claim 8 further comprising using a timer function that turns off the programmable earphone device if the wireless connection is lost for a predetermined amount of time.

15. A programmable earphone device, comprising:
a wireless transceiver that has a wireless connection to a media player;
a left and right earphone for a user's left and right ear;
a stored customizable sound equalizer comprising a left ear equalizer setting and a right ear equalizer setting, wherein the left ear equalizer setting is different from the right ear equalizer setting; and
a heartbeat monitor configured to detect a user's heartbeat using the left and right earphone, wherein the heartbeat monitor is customizable by the user.

16. A method for configuring a programmable earphone device, comprising:
testing a sensitivity of a user's left and right ears separately using the programmable earphone device, wherein the programmable earphone device comprises a left and right earphone for the user's left and right ears, to determine a difference in the sensitivity between the user's left and right ears;
calculating a left ear equalizer setting and a right ear equalizer setting, wherein the left ear equalizer setting is different from the right ear equalizer setting, using the difference in the sensitivity between the user's left and right ears; and
saving the left ear equalizer setting and the right ear equalizer setting to a non-volatile memory of the programmable earphone device.

17. The method of claim 16 wherein the testing the sensitivity of the user's left and right ears comprises playing a series of tones at different frequencies and amplitudes in a first ear, receiving feedback from the user via an input device when a played tone is heard, and repeating the playing the series of tones and receiving feedback for a second ear, thereby generating hearing data, wherein the hearing data is used to calculate the difference in the sensitivity between the user's left and right ears.

18. The method of claim 16 wherein the left ear equalizer setting and the right ear equalizer setting are saved to an EQ profile, wherein the non-volatile memory comprises a plurality of selectable EQ profiles for a plurality of users.

19. The method of claim 16 further comprising outputting sound data using the left ear equalizer setting and the right ear equalizer setting on the programmable earphone device in response to a user personal equalizer request.

20. The method of claim 16 wherein the left ear equalizer setting and the right ear equalizer setting on the programmable earphone device are usable on a plurality of different media players.

21. A programmable earphone device, comprising:
a left and right earphone for a user's left and right ear;
a wireless transceiver that has a wireless connection to a media player;
an data port, wherein the data port is configured to bypass the wireless connection and output sound data from the media player when a wired connection is detected between the media player and the programmable earphone device through the data port; and
a heartbeat monitor configured to detect a user's heartbeat using the left and right earphone, wherein the heartbeat monitor is customizable by the user.

22. The programmable earphone device of claim 21 wherein the data port is a USB port.

23. The programmable earphone device of claim 21 wherein the data port is a TRS socket.

24. The programmable earphone device of claim 21 wherein the programmable earphone device is configured to output the sound data using an EQ profile stored on the programmable earphone device, wherein the EQ profile comprises different sound equalizer settings for each of a user's left and right ears, when the wired connection is detected, and wherein the sound data is output without using the EQ profile when the wired connection is detected and the EQ profile is deactivated.

25. A method for configuring a programmable earphone device:
establishing a wired connection between the programmable earphone device and a media player;
terminating a wireless connection to the media player;
receiving sound data from the media player through the wired connection and an data port of the programmable earphone device; and
outputting the sound data on the programmable earphone device.

26. A programmable earphone device, comprising:
a wireless transceiver that has a wireless connection to a media player;
a left and a right earphone for a user's left and right ear;
at least one input means, wherein the at least one input means is located on at least one of the left and right earphones and is customizable by the user;
an data port, wherein the data port is configured to bypass the wireless connection and receive sound data from the media player when a wired connection is created between the media player and the programmable earphone device through the data port;
a stored customizable sound equalizer, wherein the stored customizable sound equalizer provides different equalizer settings for each of the left and right earphones; and
a heartbeat monitoring means configured to detect a user's heartbeat using the left and right earphone, wherein the heartbeat monitoring means is customizable by the user.

27. A system, comprising:
a programmable earphone device comprising a heartbeat monitoring application and a user interface; and
a custom user interface web service, wherein the programmable earphone device is in communication with the custom user interface web service, and the custom user interface web service is configured to allow a user to configure and reconfigure at least one of the heartbeat monitoring application and the user interface.
